(19) United States
(12) Patent Application Publication
(10) Pub. No.: US 2025/0373133 A1
(43) Pub. Date: Dec. 4, 2025

(54) POWER GENERATOR

(71) Applicant: Mountain N Meadow Holdings, Inc., Ft. Lauderdale, FL (US)

(72) Inventor: James Devericks, Ft. Lauderdale, FL (US)

(21) Appl. No.: 18/731,106

(22) Filed: May 31, 2024

Related U.S. Application Data
(60) Provisional application No. 63/505,567, filed on Jun. 1, 2023.

(51) Int. Cl. H02K 19/16; H02K 11/00; H02K 16/02; H05K 5/02

(52) U.S. Cl. CPC H02K 19/16; H02K 11/0094; H02K 16/02; H05K 5/0217

(57) ABSTRACT

The present invention combines at least one power pod having at least one Permanent Magnet Power Generator in combination with the wind, water turbines/generators and solar panels into a self-sustaining package to provide enhanced power output with little impact on the environment. In alternative embodiments, a single electric motor having an internal dynamo powered by permanent magnets, whereby operation of the motor causes the dynamo to produce power. Alternatively, the pod may include a motor having an internal alternator having rotating field coils which are rotated as the motor rotates. In addition, a small direct current dynamo may be operated by rotation of the motor to supply the DC current to the rotating field coils. This construction allows the rotating motor to produce output energy in addition to providing the rotational horsepower to rotate a gen-set or the like.

### PRIORITY CLAIM

In accordance with 37 C.F.R. 1.76, a claim of priority is included in an Application Data Sheet filed concurrently herewith. Accordingly, the present invention claims priority to U.S. Provisional Patent Application No. 63/505,567, entitled “POWER GENERATOR”, filed Jun. 1, 2023. The contents of the above referenced application are incorporated herein by reference in their entirety.

### FIELD OF THE INVENTION

The present device and system relates to power generation and, more specifically, to the area of green power generation using magnetism, solar, and fluid flow (air and water) to efficiently and economically produce power.

### BACKGROUND OF THE INVENTION

The present disclosure relates generally to the methods of providing green power to individuals off-the-grid, as well as small and large populations of individuals and industries that require much larger amounts of power. This power is generated by highly efficient and economical power pods, and the power generated by these devices is used to run everything electrical, including lighting, fans, heating and cooling (HVAC) systems, kitchen appliances, pumps, machinery, computers, medical equipment, security systems, electric vehicle charging systems, municipal lighting and water pumps, traffic signals, communications, various other electronic devices and systems, and much more.

The existing global power grids typically consist of fossil fuel and/or nuclear powered electrical power plants that contribute to pollution and/or require the storage of dangerous waste and byproducts for many years after the useful life of those fuel sources have been depleted. Furthermore, the carbon footprint required to manufacture many forms of these power plants is enormous. And, after the construction of the power plants, the carbon footprint continues to grow as mining, fracking, transport of raw materials, and refinement are required to keep these power plants running.

Even with the recent demonstrations and breakthroughs in nuclear fusion, the functionality, logistics and economics of nuclear fusion have not yet been sorted out and scaled for commercial use. It will likely take another 50+ years for the technology to evolve where it is practical for widespread use.

There are other less damaging forms of power generation, including solar, wind, and water power, that are far less impactful to the environment and not very efficient (in the sense that it takes a great number of solar panels or wind turbines to generate a relatively small amount of power), like a wind turbine farm, to produce enough energy to power just a small town. The carbon footprint required to manufacture most of these green energy solutions also requires a great deal of power, mining, transportation, and hazardous byproducts, but may not require the ever-growing carbon footprint that fossil fuel and nuclear power plants require. So, while all of these green energy solutions have a lower operational carbon footprint, it may be difficult to efficiently provide power to large populations and industry.

For individuals or small populations living off-the-grid, generators that run on fossil fuels (e.g. gasoline, diesel, propane, etc.) are often an option for portions of any given day but tend to be quite expensive and noisy, both audibly and electrically, to run all day every day. These methods of power generation also have large carbon footprints. Solar, wind, and water power generation may be just marginally good enough to provide for some of the most basic electrical power demand needs for these individuals.

### DESCRIPTION OF THE PRIOR ART

U.S. Pat. No. 11,336,134 to Holcomb discloses a solid state rotary field electric power generation device. U.S. Pat. No. 8,593,102 to McGuire discloses a portable self-sustaining power station. U.S. Pat. No. 13,037,010 to McGuire discloses a portable self-sustaining power station.

### SUMMARY OF THE INVENTION

While there are countless wind and water turbines/generators and solar panels on the market, the present invention combines at least one power pod having at least one Permanent Magnet Power Generator in combination with the wind, water turbines/generators and solar panels into a self-sustaining package to provide enhanced power output with little impact on the environment. In alternative embodiments, a single electric motor having an internal dynamo powered by permanent magnets, whereby operation of the motor causes the dynamo to produce power. Alternatively, the pod may include a motor having an internal alternator having rotating field coils which are rotated as the motor rotates. In addition, a small direct current dynamo may be operated by rotation of the motor to supply the DC current to the rotating field coils. This construction allows the rotating motor to produce output energy in addition to providing the rotational horsepower to rotate a gen-set or the like.

Thus, it is an objective of the present invention to provide a self-sustaining power pod capable of controlling the generation and distribution of electrical power.

It is also an objective of the present invention to provide a power pod that utilizes at least one solid state rotary field electric power generation device.

It is another objective of the present invention to provide a power pod that utilizes at least one solid state rotary field electric power generation device in combination with known electrical generation devices wherein the power from multiple power generation devices is aggregated before distribution.

It is still yet another objective of the present invention to provide a power pod that includes at least one battery for storage and distribution of generated power.

It is a further objective of the present invention to provide a power pod that includes at least one graphene battery for storage and distribution of generated electrical power.

An even further objective of the present invention is to provide a power pod where a portion of the power stored on at least one graphene battery is used to start and continue power generation within the solid state rotary field electric power generation device.

Other objectives and advantages of this invention will become apparent from the following description taken in conjunction with any accompanying drawings wherein are set forth, by way of illustration and example, certain embodiments of this invention. Any drawings contained herein constitute a part of this specification, include exemplary embodiments of the present invention, and illustrate various objects and features thereof.

### BRIEF DESCRIPTION OF THE FIGURES

FIG. 1 is a front perspective view of a Permanent Magnet Power Generator (power pod) with doors closed;

FIG. 2 is a front perspective view of the power pod with doors opened;

FIG. 3 is a rear perspective view of the power pod with doors closed;

FIG. 4 is a right side view of the power pod with doors closed;

FIG. 5 is a front view of the power pod with the doors opened;

FIG. 6 is a top view of the power pod with the doors closed;

FIG. 7 is a cross-sectional view of the power pod with the doors closed;

FIG. 8 is a battery connection diagram;

FIG. 9 is a grid inverter connection diagram;

FIG. 10 is a direct grid connection diagram;

FIG. 11 is a multi-pod connection diagram;

FIG. 12 is an end view of a power pod container having an electronic lock for the doors;

FIG. 13 is a partial end view of a power pod illustrating an alternative embodiment of the electronic door lock;

FIG. 14 is a partial end view of a power pod taken along lines 14-14 of FIG. 12 illustrating the electronic door lock;

FIG. 15 is a perspective end view of a power pod having an electronic door lock;

FIG. 16 is an end view of a power pod illustrating an electronic door lock;

FIG. 17 is a partial end view taken along lines 17-17 of FIG. 16 illustrating the electronic door lock;

FIG. 18 is a partial rear view illustrating an electronic door lock;

FIG. 19 is a perspective view illustrating a HVAC unit secured to a power pod;

FIG. 20 is a schematic side view of the HVAC unit illustrated in FIG. 19 secured within the power pod wall;

FIG. 21 is a schematic top view of the HVAC unit illustrated in FIG. 19 secured within the power pod wall;

FIG. 22A is a front view of the HVAC unit illustrated in FIG. 19;

FIG. 22B is a side view of the HVAC unit illustrated in FIG. 19;

FIG. 22C is a rear view of the HVAC unit illustrated in FIG. 19; and

FIG. 22D is a top view of the HVAC unit illustrated in FIG. 19.

### DETAILED DESCRIPTION OF THE INVENTION

While the present invention is susceptible of embodiment in various forms, there is shown in the drawings and will hereinafter be described presently preferred, albeit not limiting, embodiments with the understanding that the present disclosure is to be considered exemplifications of the present invention and not intended to limit the invention to the specific embodiments illustrated.

As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” “perspective” and derivatives thereof, shall relate to the invention as oriented in the Figures. Furthermore, there is no intention to be bound by any expressed or implied theory presented in the preceding technical field, background, abstract, or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise. References to green power generators throughout this document are general statements and are exemplary or illustrative of typical use for the purpose of explaining this design. Furthermore, the power pod will be interchangeably referred to as “device” or “module” or “apparatus” or “POD” throughout this document.

Generally, the power pod 10 is an autonomously running green-power generation device that adjusts its power output based upon the demand of electrical devices electrically attached to it. While the power pod is monitored remotely from a central control facility, it is the intent of at least one embodiment of this invention that the electrical control system 136 will run autonomously. The power pod electrical control system 136 includes software that allows automatic shutdown in the event that predetermined operating parameters are exceeded. Other events that might also result in a shutdown might include excessive heat, fire, theft, vandalism, or tampering with the device.

A power pod 10 includes several main components. These components include the container 100, one or more magnetic generators 126, an electrical control system 136, battery power 146 (stored power), solar panel power 102, wind turbine power 106, communications 104, 112, climate control 110, 128, security system 148, 152, and more.

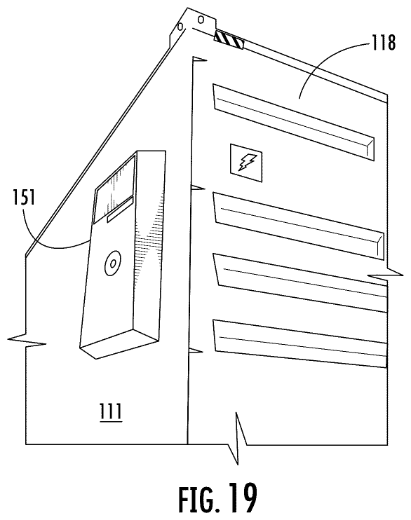

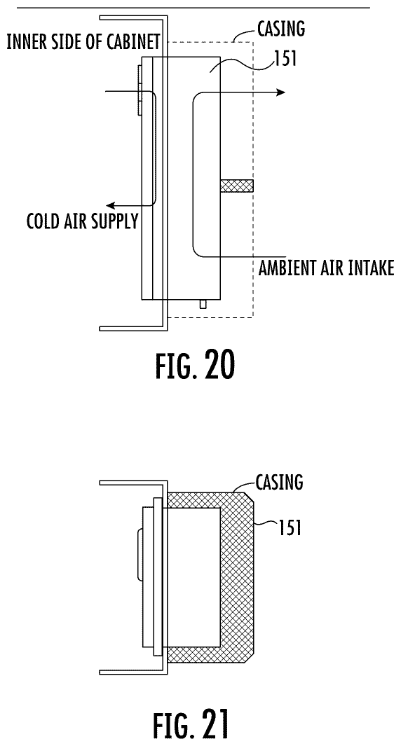

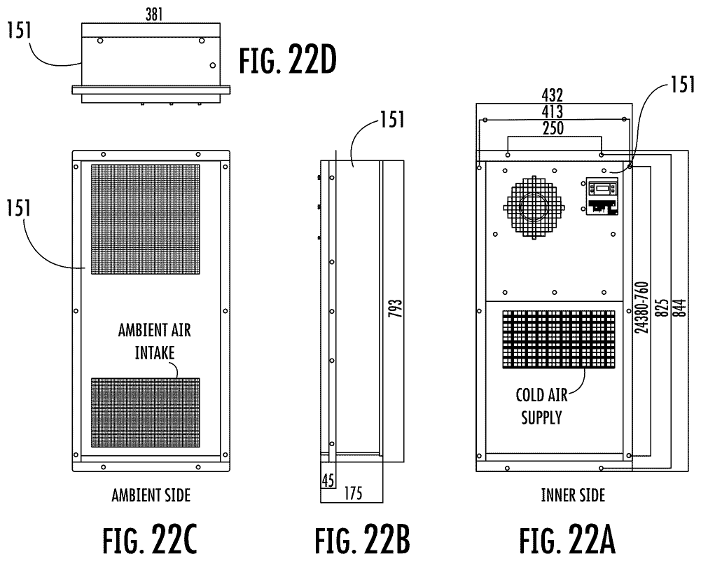

The container 100 is essentially constructed from rigid panels 111 to define a protective shell 113 that shields the most sensitive internal power pod components against the elements, theft, vandalism, and/or tampering. The walls 101 of the container are preferably insulated and heated/cooled with circulation tubes 103 filled with ethylene glycol, or similar chemical(s), spaced apart and extending throughout the rigid panels, and in some embodiment the tubes 103 may further extend through functional outer cosmetic features 114, and through various internal manifolds (not shown) within the container 100. Alternatively, a through wall heating ventilation and air conditioning system (HVAC system) (FIGS. 19-22D) may be utilized without departing from the scope of the invention.

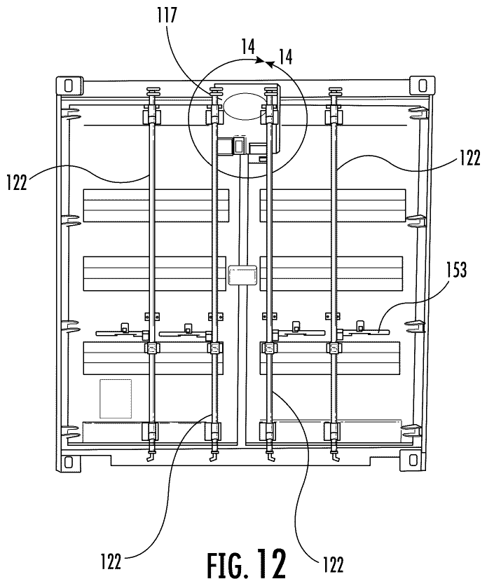

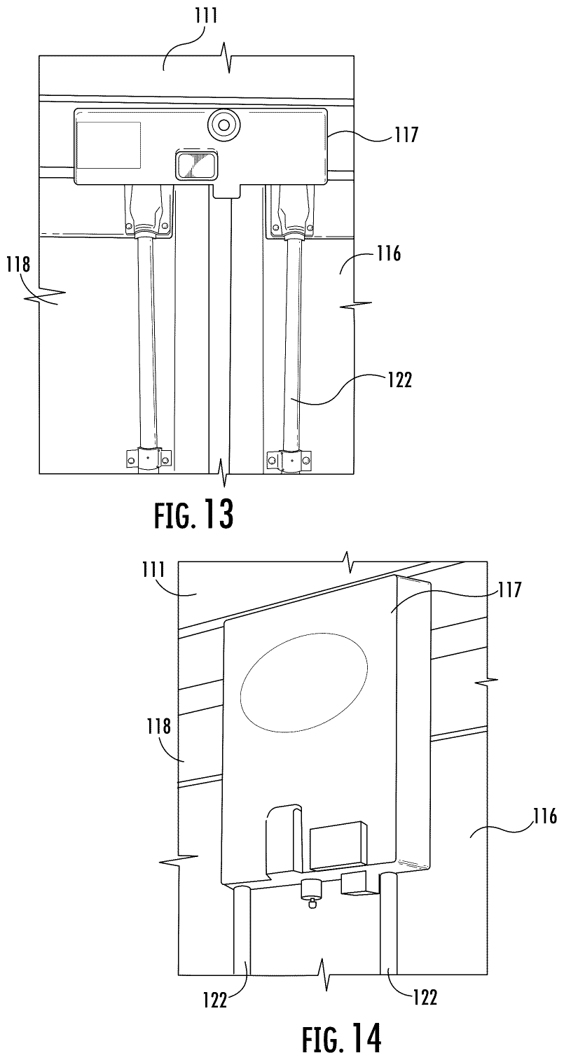

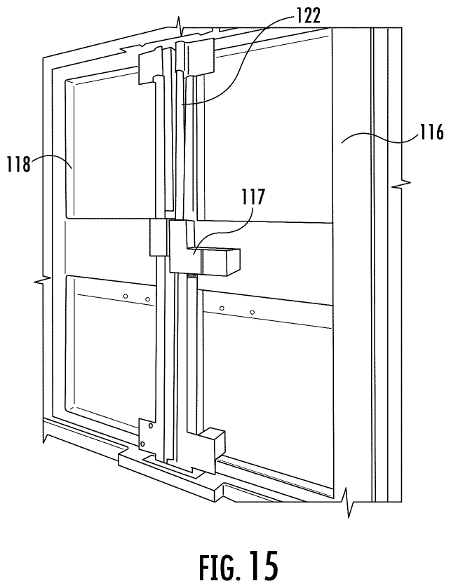

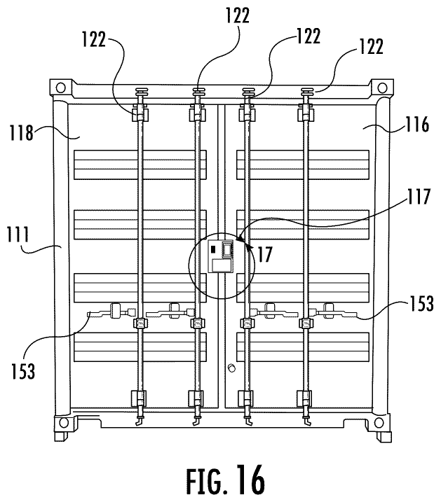

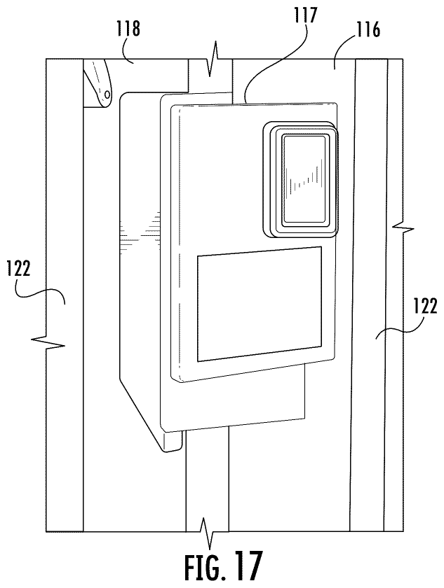

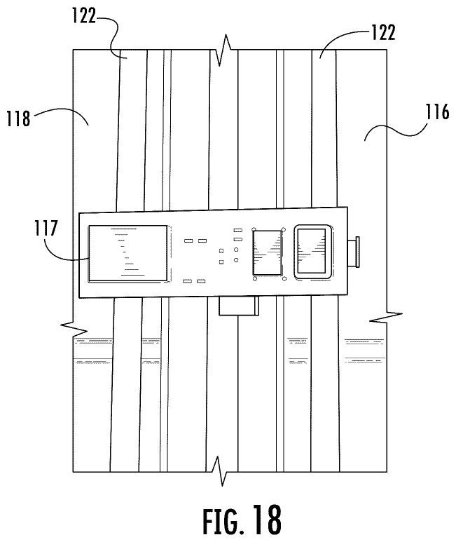

The container 100 has at least one point of entry 99 that preferably includes two main opposing hinged doors 116, 118 at an end portion of the container, including a right door assembly 116 and a left door assembly 118. Heavy gauge bars 122 bolt the top and bottom ends of each of the doors to the perimeter of the door opening and possibly to one another. Through a mechanism of levers and mechanical advantage, the doors can be opened manually when a remotely operated electromechanical lock 117 is released. The locking/unlocking action to release the bars 122 and levers 153 can be accomplished with an electromechanical mechanism from a remote location using encrypted communication over a satellite 104 and/or 5G 112 connection with respective transceivers to provide limited access to the power pod 10. The electromechanical lock may engage the bars 122 to prevent rotation or translation thereof as shown in FIGS. 12-15 and 18. Alternatively, the electromechanical lock 117 may secure the right door panel 116 and the left door panel 118 together as shown in FIGS. 16 and 17.

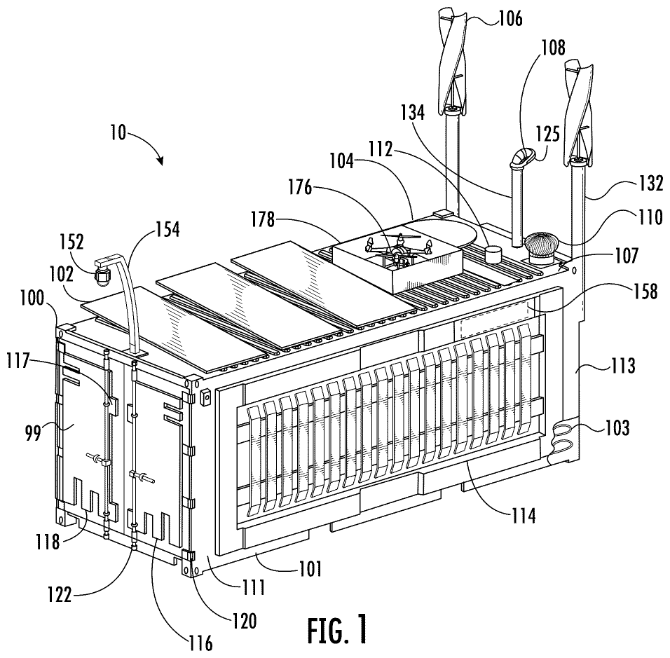

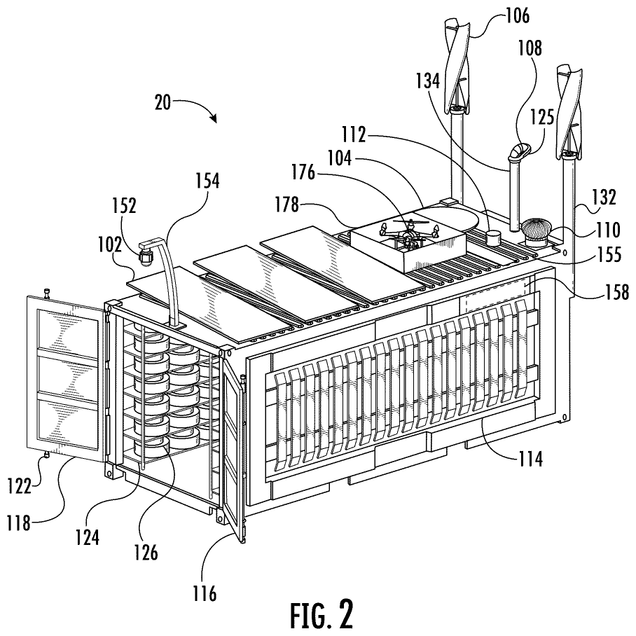

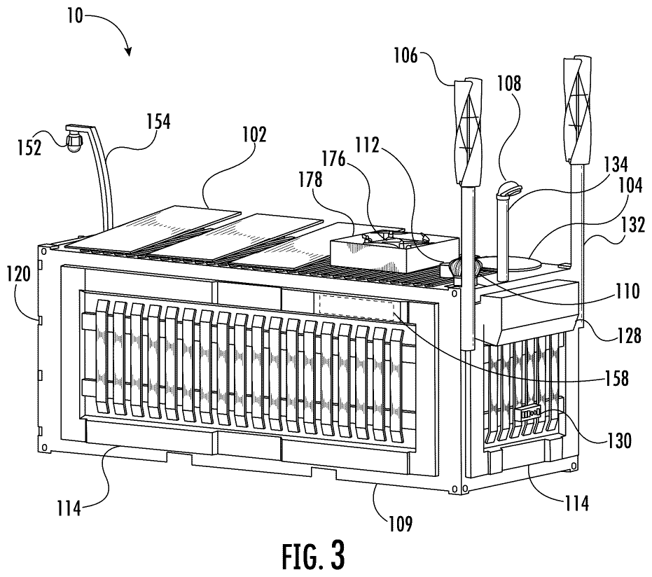

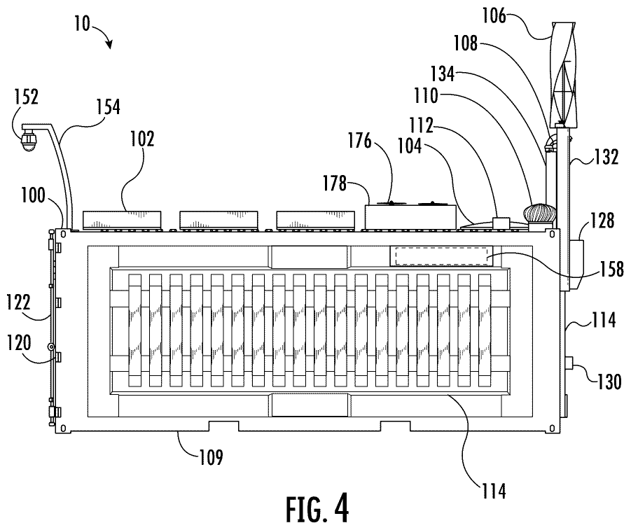

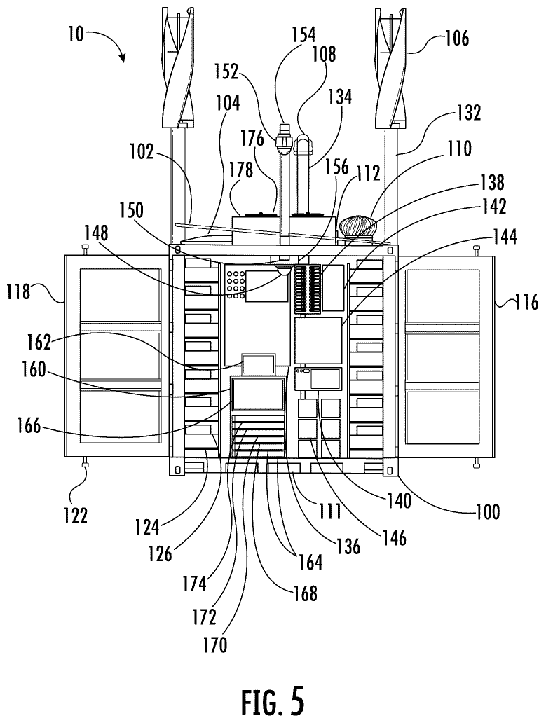

External security for each power pod 10 may be provided by motion sensors 105 (FIG. 1) and one or more IP (internet protocol) controlled PTZ (pan tilt zoom) dome cameras 152. The dome cameras 152 may include integrated motion detection functionality, as is known in the art. The camera(s) can be mounted externally on risers 154 (elevated brackets) to provide for somewhat of a “birds eye” view of the container 100 and the surrounding area, as well as internally to monitor theft, vandalism, tampering, maintenance, breaches, fire, and any other event that might occur with a power pod.

Cosmetic panels 114 may adorn the outside of the container 100 to give the container a unique aesthetic look. These cosmetic features may be located on any surface of the container, but likely on the lateral sides and ends thereof. The top 107 and bottom 109 surfaces will preferably be constructed for stacking power pods during shipping. The various features may also provide cooling/heating functionality, as coolant can be pumped through cavities or tubes 103 within the various features in the cosmetic panels to exchange heat between the interior of the power pod and the exterior of the power pod.

One or more unique identification labels 158 with alpha-numeric code will be attached to the container so that the container can be identified from the air or ground from a distance with the naked eye, binoculars, or even satellite imagery. A unique beacon signal (e.g. MAC address, IP address, etc.) will also be output over an encrypted satellite transceiver 104 through bidirectional or 5G 112 communication and may include satellite 133 communication on a scheduled basis to a central control facility 131 for further identification and to provide the current status and GPS location of each power pod. This same unique identifier will also be used for individuals to gain access to the power pod for configuration, maintenance, and upgrades.

Internal lighting 156 may be installed within each power pod for the purpose of configuration, maintenance, and upgrades. The lighting will provide illumination for maintenance crews to work within a power pod without the need for headlamps or alternate lighting sources.

Ventilation 155 may be created through a cooling fan 110 on the roof of the container. The ventilation 155 may be opened/closed using an electrically controlled damper to prevent the infiltration of rain, snow, sand (sandstorms), or any other contaminants from any other meteorological or manmade event that might impede the performance of the internal components of the power pod 10.

Internal environmental controls including cooling/heating and humidity (HVAC) control are further provided using a climate control system 128. The system will utilize conventional air-conditioning using the refrigeration cycle (sometimes referred to as the heat pump cycle) in cooperation with the cooling fan or heater coils to provide the appropriate temperature and humidity control for the systems within the container. Such systems are available from COOLTECH, located at 182 Hair Road, Quingdao, Shandong, China, as shown in FIGS. 19-22, which feature a through wall HVAC system 151 to conserve space within the power pod 10. Further cooling and heating may be provided by pumping coolant through the external cosmetic panels as a heat exchanger, as mentioned earlier in this description. The absence of a climate control system might lead to early component failure due to excessive cold, heat, and/or humidity.

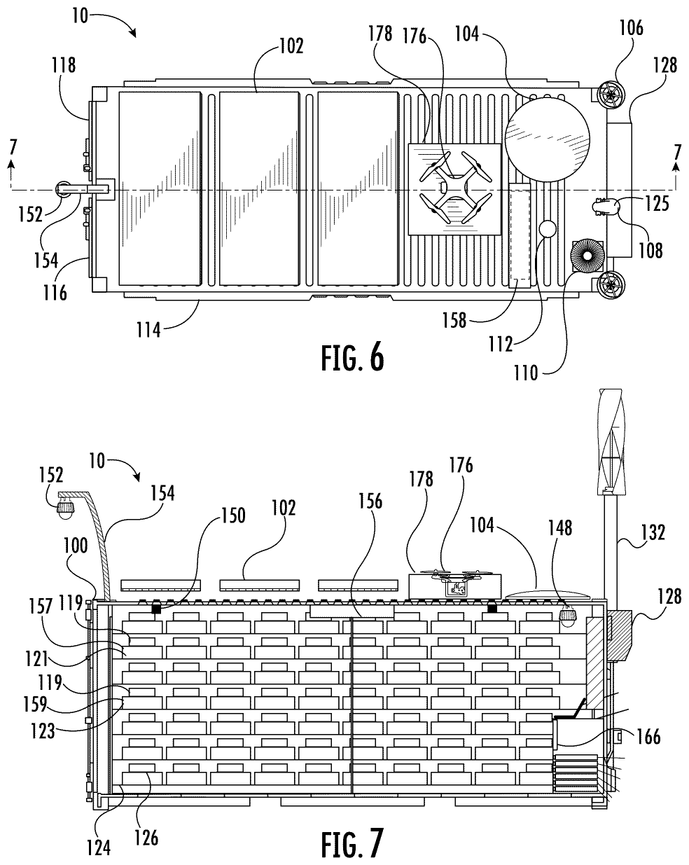

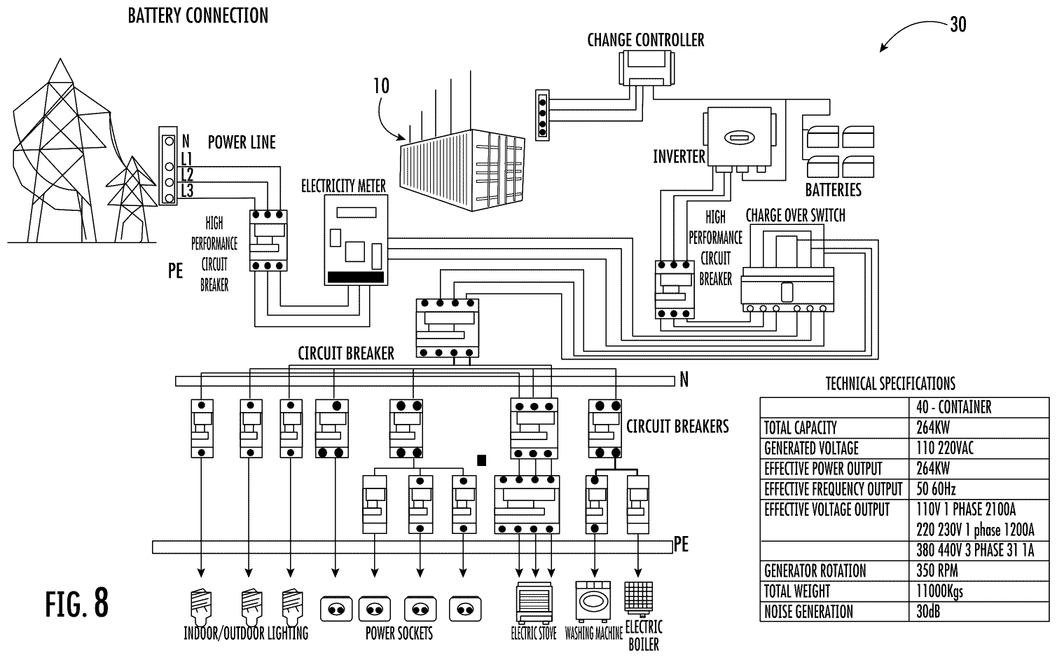

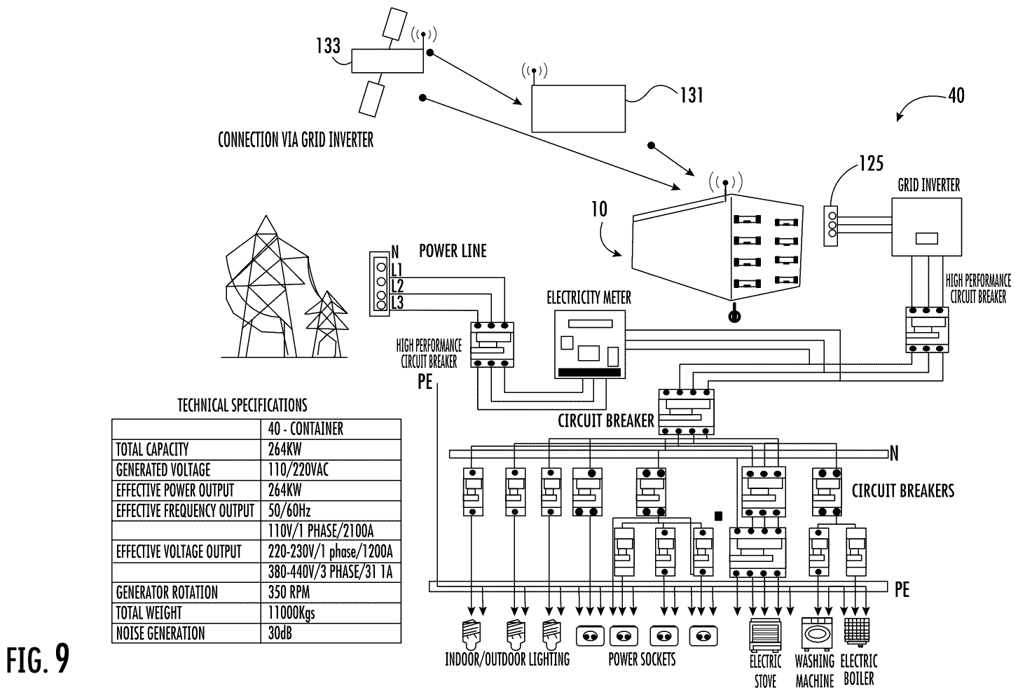

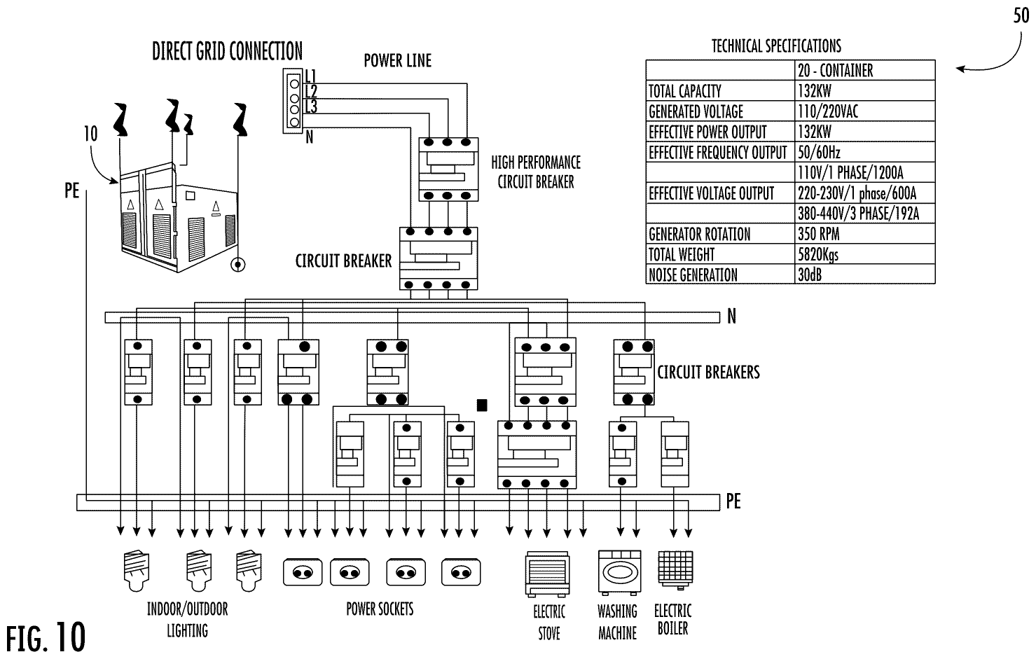

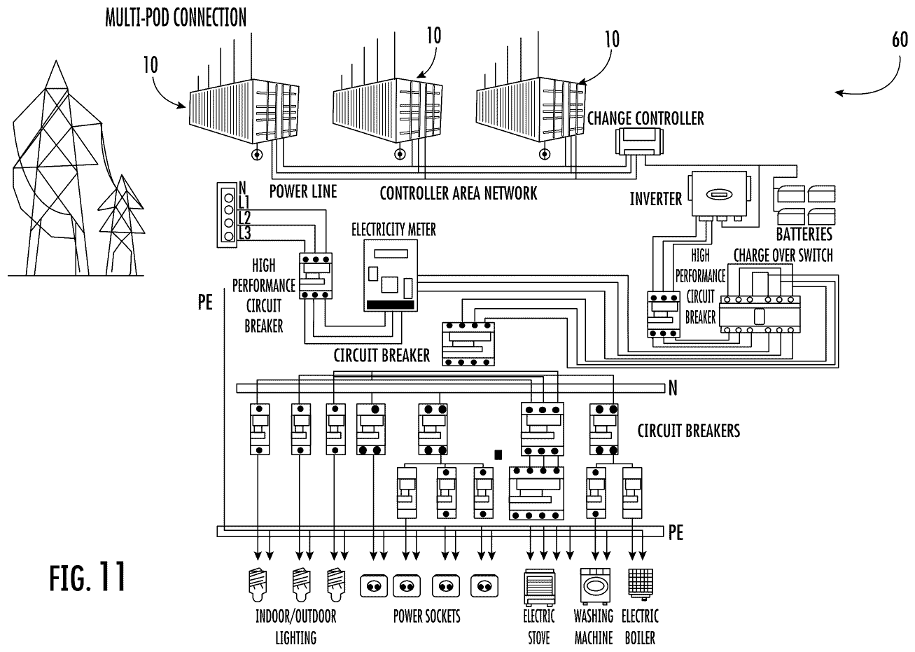

The core green-energy-producing component of the power pod is the magnetic generator 126 and the electrical control system 136. The magnetic generator of the preferred embodiment is a rotary field electric power generation device. The magnetic generator 126 is constructed and arranged to have at least one rotating rotor 119 (FIG. 7) for providing mechanical work out of the magnetic generator, the magnetic generator also having at least one power generation circuit internal to the magnetic generator, a portion of the power generation circuit constructed and arranged to rotate with the at least one rotating rotor 119 during rotation of the at least one rotating rotor to generate electrical power during rotation thereof, the generated power electrically connected to an electrical control system 136; the electrical control system including at least one battery 146 and at least one electrical output 125 (FIGS. 1 and 6), the electrical control system 136 directing power to at least one battery 146 within the power pod 10 or to one or more electrical devices outside of the power pod assembly. The electrical control system 136 is constructed and arranged to direct the power out of the power pod based upon the electrical demand of the one or more electrical devices electrically attached to the power pod, with remaining power to be directed to the at least one battery 146. In the preferred embodiment, the at least one rotating rotor 119 of the magnetic generator 126 is operably connected to a generator 121 or an alternator 123 for providing rotation to the generator or alternator rotor 157, 159. In this manner, the magnetic generator 126 is used to generate power in a conventional manner and produces additional power from the internal power generation circuit.

It should be noted that other magnetic power generators that include an ability to generate power in addition to mechanical power generation may be utilized without departing from the scope of the invention. The magnetic generator 126 preferably has very few moving parts, and the electrical control system 136 can be used to control the switching of the magnetic fields within the magnetic generator in order for the magnetic generator to operate.

At least one magnetic generator 126 will be housed within the container 100. It is likely that numerous magnetic generators 126 will be used within each container 100. These magnetic generators 126 will be placed on racks 124, or shelves, within the container and will all be wired into the electrical control system 136. The electrical control system 136 will be able to accommodate a large number of magnetic generators 126 in a “smart” plug-and-play manner with little or no configuration required. This will allow the system to continue running properly in the event one or more magnetic generators fail or are replaced.

Alternate means of green power generation are provided by one or more solar panels 102 and/or one or more wind turbines 106. The solar panels 102 can vary in size and be placed at various angles to optimize the power generation based upon the global location of the container. The wind turbines 106 can be vertical wind turbines as shown in the illustrations, or they can be any one of another variety of other vertical-axis or horizontal-axis wind turbines (VAWT or HAWT, respectively). The turbines are elevated on risers 132 to provide better exposure to wind. The energy generated by solar and wind is stored in one or more batteries 146 that are housed within the container 100.

All of the top-mounted hardware, including solar panels 102, wind turbines 106, satellite 104 and 5G 112 antennas and transceivers, IP/PTZ dome cameras 148, 152, weather head(s) 108, and other hardware will all be collapsible or removable during transport. This will facilitate the ability to stack the power pods one on top of another for shipping.

These alternate methods of green power generation are in place to provide the required power to start the magnetic generators 126 in much the same manner as a jet aircraft engine uses a power generator to get the turbine spinning prior to combustion. A power storage medium, such as graphene batteries 111, is used to store power for distribution or for starting the magnetic generator 126. Once one magnetic generator is powered up, the power produced by that magnetic generator can be used to “fire up” the remaining magnetic generators in a sequence until all of the magnetic generators in a single power pod are powered up.

The electrical control system 136 within the container 100 includes power management and safety components including a controller 166, inverter 144, power meter 140, circuit breaker panel 138, change-over switch 142, fire suppression 150, lighting 156, security camera(s) 148, and more. Each of these components helps to manage the power generation, safety, and distribution to the “outside world”.

Power to the outside world can be configured in many ways, including battery connection 30, connection via grid inverter 40, direct grid connection 50, multi-pod connection 60, direct connection to the receptacles in the receptacle panel 130, and any combination of the above and more. These various configurations allow for the power pod to provide the appropriate power output based upon the power demand.

In a conventional configuration, the power from the power pod will be output through power output wires 125 that exit through a weather head 108 that sits atop a riser 134 and protrudes from the roof of the container with a drip loop to prevent water from dripping into the power pod. The riser 134 elevates the high power wires to place the wires out-of-reach for human beings. In many areas this elevation is a building code requirement.

One of the power pods might act as a master and the others as slaves, with the change converter located in the master power pod. In the event of a power pod failure, one of the slave power pods would automatically change its configuration from slave to master and assume the master role of multi-pod power management and change over.

Power may also be provided in a direct connection configuration using extension cords connected directly to the outlet receptacle panel 130 that houses 120V and 240V receptacles. These can be configured to different voltages and frequencies based upon the global location of the power pod and the local standards for voltage and frequency.

The power pod can be monitored and controlled via satellite 104 and 5G 112 (or higher generation) encrypted communication. This also includes a GPS radio that can provide the geographical location of each and every power pod.

One or more IP controlled pan/tilt/zoom (PTZ) cameras 148, 152 may be installed internal to the container and external to the container in order to identify problems relating to the state of the power pod, including power pod maintenance and repair, weather conditions, theft/vandalism/tampering, and more. The communication over satellite and 5G will provide for security and remote lock/unlock entry/exit for the power pod.

The communication over satellite and 5G will provide for security and remote lock/unlock entry/exit for the power pod. Additionally, a drone 176 that is stored in a drone cage (drone garage) 178 may be mounted on the roof of the crate for perimeter security monitoring. Additionally, the drone may be configured to provide a mobile cell hot spot, whereby the drone may be flown over areas that have been devastated by storm or the like to provide internet and mobile phone access to those in the area.

The power pod device will be relatively inexpensive to manufacture as they may be manufactured with readily available off-the-shelf shipping containers. The containers can be made from steel, aluminum, fiberglass, continuous basalt fiber, and more, or a combination of materials to provide for the highest strength for security and stackablity, and the lowest mass for the purpose of shipping and lifting.

All patents and publications mentioned in this specification are indicative of the levels of those skilled in the art to which the invention pertains.

It is to be understood that while certain forms of the invention are illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary, and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A power pod assembly 10 comprising:
a power pod 10 including a container 100, the container 100 being constructed from a plurality of rigid panels 111 to define a protective shell 113 that shields the internal components of the power pod 10 against damage from the elements, theft, vandalism, and tampering, the container 100 has at least one point of entry 99 that includes a right door assembly 116 and a left door assembly 118, bars 122 secure the top and bottom ends of each of the doors to the perimeter of the door opening, an electromechanical locking mechanism 117 for controlling the ability to open the left and right door assemblies 116, 118, wherein operation of the electromechanical locking mechanism 117 can be accomplished from a remote location,
at least one magnetic generator 126, the magnetic generator being constructed and arranged to have at least one rotating rotor 119 for providing mechanical work out of the magnetic generator, the magnetic generator also having at least one power generation circuit, a portion of the power generation circuit constructed and arranged to rotate with the at least one rotating rotor during rotation of the at least one rotating rotor to generate electrical power during rotation thereof, the generated power electrically connected to an electrical control system 136, the electrical control system including at least one battery 146 and at least one electrical output 125, the electrical control system 136 directing power to at least one battery 146 within the power pod 10 or to one or more electrical devices outside of the power pod assembly, the electrical control system is constructed and arranged to direct the power out of the power pod based upon the electrical demand of the one or more electrical devices electrically attached to the power pod, with remaining power to be directed to the at least one battery 146.

2. The power pod assembly 10 of claim 1 wherein the at least one rotating rotor 119 of the magnetic generator 126 is secured to a generator 121 for providing rotation to the generator rotor 157.

3. The power pod assembly 10 of claim 1 wherein the at least one rotating rotor 119 of the magnetic generator 126 is secured to an alternator 123 for providing rotation to the alternator rotor 159.

4. The power pod assembly 10 of claim 1 wherein the power pod assembly 10 includes a plurality of solar panels 102 electrically connected to the electrical control system 136, the electrical control system 136 directing power generated by the plurality of solar panels to at least one battery 146 within the power pod 10 or to one or more electrical devices outside of the power pod assembly based upon the electrical demand of the one or more electrical devices electrically attached to the power pod.

5. The power pod assembly 10 of claim 1 wherein the power pod assembly 10 includes a plurality of wind turbines 106 electrically connected to the electrical control system 136, the electrical control system 136 directing power generated by the plurality of wind turbines to at least one battery 146 within the power pod 10 or to one or more electrical devices outside of the power pod assembly based upon the electrical demand of the one or more electrical devices electrically attached to the power pod.

6. The power pod assembly 10 of claim 1 wherein the power pod 10 operates autonomously and is monitored remotely from a central control facility 131.

7. The power pod assembly 10 of claim 6 wherein the central control facility 131 includes bi-directional satellite 133 communication, wherein both the satellite and the central control facility are constructed and arranged to communicate with the power pod 10.

8. The power pod assembly 10 of claim 7 wherein the remote operation of the electromechanical locking mechanism 117 is accomplished using encrypted communication over the bi-directional satellite communication 133.

9. The power pod assembly 10 of claim 8 wherein the power pod includes a satellite transceiver 104 for bi-directional communication with satellite 133.

10. The power pod assembly 10 of claim 7 wherein the remote operation of the electromechanical locking mechanism 117 is accomplished using encrypted communication over a 5G network.

11. The power pod assembly 10 of claim 1 wherein the electrical control system 136 includes software constructed and arranged to monitor the magnetic generator 126 and at least one battery 146 to provide automatic shutdown in the event that predetermined maintenance thresholds are exceeded.

12. The power pod assembly 10 of claim 11 wherein the critical maintenance thresholds are selected from the group consisting of excessive heat, fire, theft, vandalism or device failure.

13. The power pod assembly 10 of claim 7 wherein the electrical control system 136 is constructed and arranged to transmit the current status and GPS location of each power pod on a scheduled basis to the central control facility 131.

14. The power pod assembly 10 of claim 1 wherein a rigid roof panel 111 of the container 100 includes a drone cage 178 for storing a drone 176 for perimeter security monitoring of the power pod 10.

15. The power pod assembly 10 of claim 14 wherein the drone 176 is configured to provide a mobile cell hot spot, wherein the drone 176 may be flown over areas to provide internet and mobile phone access to those within wireless signal range.
